(19) United States
(12) Patent Application Publication
(10) Pub. No.: US 2023/0402970 A1
(43) Pub. Date: Dec. 14, 2023

(54) THERMAL CONTACT SHEET FOR PHOTOVOLTAIC THERMAL COLLECTOR

(71) Applicants: João Santos Gomes, Uppsala (SE); Tony Bjorklund, Alvkarleby (SE)

(72) Inventors: João Santos Gomes, Uppsala (SE); Tony Bjorklund, Alvkarleby (SE)

(21) Appl. No.: 17/935,165

(22) Filed: Sep. 26, 2022

Related U.S. Application Data
(60) Provisional application No. 63/366,251, filed on Jun. 12, 2022.

(51) Int. Cl. H02S 40/40; F28F 3/00

(52) U.S. Cl. CPC H02S 40/40; F28F 3/00

(57) ABSTRACT

A thermal contact sheet for a photovoltaic thermal collector comprises a sheet configured to provide thermal contact between a plurality of photovoltaic cells and a heat exchanger comprising a working fluid in the photovoltaic thermal collector. The sheet comprises a plurality of through holes shaped and arranged on the sheet so as to provide thermal expansion resistance of the sheet in a plurality of directions, by absorbing at least part of the thermal expansion of the sheet into the through holes. A photovoltaic thermal collector comprising a thermal contact sheet is also described.

### STATEMENT REGARDING PRIOR DISCLOSURES BY THE INVENTOR OR A JOINT INVENTOR

The following disclosure is submitted under 35 U.S.C. 102(b)(1)(A): DISCLOSURE: “Development of Concentrating Photovoltaic-Thermal Solar Collectors”, João Santos Leite Cima Gomes, Gävle University Press, ISBN 978-91-88145-67-3, made publicly available on Aug. 27, 2021.

### BACKGROUND

The present invention relates to Photovoltaic (PV) cells, and more specifically to Photovoltaic Thermal Collectors (PVTs).

Energy use is one of the major contributors to climate change. One important way to combat climate change is therefore to convert to low-carbon dioxide emitting energy sources, preferably renewable ones, which are sustainable in the long run. Significant efforts have been put into developing various ways to use the energy from solar irradiance, to generate electricity (“solar electricity”), and heat (“solar heat”), respectively.

Solar electricity is either produced by the photovoltaic (PV) effect, or by the conversion of solar irradiation into high temperature heat that is used to drive a turbine that generates electricity. Solar heat, also referred to as or Solar Thermal (ST), is the process of converting solar irradiation into heat. A large number of different ST technologies exists, ranging from uncovered flat plate collectors, to vacuum tube collectors or large tracking, concentrating solar collectors. These technologies produce heat at different temperatures and therefore have multiple applications, such as in residential and industrial sectors.

A Photovoltaic Thermal (PVT) collector can be generally characterized as a “hybrid” solar electricity and solar thermal collector, which converts solar radiation into both usable thermal and electrical energy. PVT collectors combine PV solar cells with an ST collector, which transfers the otherwise unused waste heat from the PV module to a heat transfer fluid, such as water, water with glycol, or mineral oil. By combining electricity and heat generation within the same component, these technologies can reach a higher overall efficiency than a same area of PV and ST collectors. PVT collectors combine the generation of solar electricity and heat in a single component, and thus achieve a higher overall efficiency and better utilization of the solar spectrum than conventional PV modules.

In a PVT collector, the working fluid circulates in the heat exchanger behind the PV cells, and the heat from the PV cells is conducted through the metal and absorbed by the working fluid (if the working fluid is cooler than the cells, electric efficiency will be increased). The working fluid is subsequently used by other systems, such as space heating systems (domestic, industrial), water heating systems, water desalination, space cooling, food processing systems and more.

For PVTs to be a viable alternative energy source, it is essential to achieve a connection between electrical and thermal parts of the collector, which both has a sufficient electrical resistance but at the same time, a good heat conductivity. This is typically difficult to achieve, especially while still maintaining other desired properties of the PVT, such as transmissivity, cost, thermal expansion resistance, efficient mass production processes, durability and so on. A common solution is to encapsulate the solar cells with Ethylene-vinyl acetate (EVA). This solution is inexpensive and provides good protection to the solar cells. However, EVA cannot withstand temperatures above the range of 800 to 120° C., and since most PVT collectors can easily reach temperatures above 120° C. under stagnation, EVA is not a feasible solution for encapsulation in glazed and concentrating PVT collectors. In addition, most materials that have high thermal conductivity are also electrically conductive, which is not desirable from a safety point of view.

### SUMMARY

In some aspects, the techniques described herein relate to a thermal contact sheet for a photovoltaic thermal collector. The sheet is configured to provide thermal contact between a plurality of photovoltaic cells and a heat exchanger comprising a working fluid in the photovoltaic thermal collector. The sheet comprises a plurality of through holes shaped and arranged on the sheet so as to provide thermal expansion resistance of the sheet in a plurality of directions, by absorbing at least part of the thermal expansion of the sheet into the through holes.

In some embodiments, the sheet is made from one of the following materials: aluminum, aluminum alloys, copper, ceramics, brass, fiber plastics, and plastics.

In some embodiments, the sheet has a thickness in the range of approximately 0.2 mm to 4.0 mm.

In some embodiments, the through holes are shaped to allow absorption of thermal expansion in two perpendicular directions.

In some embodiments, at least some of the through holes are shaped as slits.

In some embodiments, the through holes are shaped similar to one or more of the letters H, L, M, C, Z or W.

In some embodiments, the through holes are evenly distributed across the sheet.

In some embodiments, the distance between the holes is in the range of approximately 3-30 mm.

In some embodiments, the combined cross-sectional area of the through holes is in the range of approximately 7-70 percent of the surface area of the portion of the sheet that is located directly below the photovoltaic cells.

In some embodiments, the sheet further comprises an electrical insulation on one or both sides of the sheet.

In some embodiments, the electrical insulation is achieved by a powder coating, an insulating film or anodization.

In some embodiments, the through holes are filled with an encapsulant to increase the protection of the photovoltaic cells against thermal expansion and contraction of the thermal contact sheet.

In some embodiments, the encapsulant is silicone or Ethylene-vinyl acetate.

In some aspects, the techniques described herein relate to a photovoltaic thermal collector comprising a thermal contact sheet as described above.

The details of one or more of these embodiments of the invention are set forth in the accompanying drawings and the description below. Other features and advantages of the invention will be apparent from the description and drawings, and from the claims.

### BRIEF DESCRIPTION OF THE DRAWINGS

FIG. 1 shows an exploded view of a PVT collector, in accordance with some embodiments.

FIG. 2 shows a schematic block diagram of the different layers of a PVT collector, in accordance with some embodiments.

FIG. 3 shows a perspective view of a receiver core of a PVT collector, in accordance with some embodiments.

FIG. 4 shows a top view of an embodiment of the thermal contact sheet.

Like reference symbols in the various drawings indicate like elements.

### DETAILED DESCRIPTION

The various embodiments of the invention address the various above-mentioned issues by improving thermal contact between the cell and receiver in a PVT collector while maintaining electrical insulation, reducing the thermal stress on the cells, reducing the amount of expensive encapsulant utilized, simplifying the production process and the production times, etc.

In particular, a thermal contact sheet for a PVT collector is provided. The thermal contact sheet has a plurality of through holes arranged in a geometric pattern, thereby allowing improved thermal contact and increased reliability with regards to electrical insulation and thermal expansion (durability), while at the same time allowing cost savings in components, such as the encapsulant. In some embodiments, the through holes have a shape similar to the letter H and is thus referred to as a “H-pattern.” The thermal contact sheet with the H-pattern is a metal structure (e.g., aluminum) that is located between the solar cells and the receiver of a PVT collector, allowing for improved heat conduction while at the same time protecting the solar cells from the thermal expansion of the receiver. As will be described in further detail below, some embodiments include a pre-insulated layer on the thermal contact sheet, with high electrical resistance that is expected to enable the solar cells to be kept in contact with the aluminum receiver further improving the heat conduction, improving cell efficiency (cell operates at lower temperature), and increasing the thermal efficiency of the collector. It is important to note that the H-pattern is merely one possible embodiment, and that there may be several other patterns that can achieve the same technical purpose, as will be described in further detail below.

The novel PVT designs described herein have an improved performance, both thermally and electrically. Furthermore, the durability is improved, as the thermal stress on the cells is reduced. Lastly, the design allows for a reduction in cost, both in terms of production time and component costs, as the thermal contact sheet with the hole pattern is both cheaper than a conventional transparent encapsulant, and also faster to cure and apply.

The novel design also uses significantly less encapsulant per receiver, which is one of the most expensive receiver components. Many encapsulant, such as silicone, have a poor thermal conductivity, but a good resistance to thermal expansion and contraction. In some of the embodiments that will be described below, the encapsulant is silicone but a wide range of other materials are also possible, even including EVA, assuming the temperature of the PVT collector can be appropriately controlled.

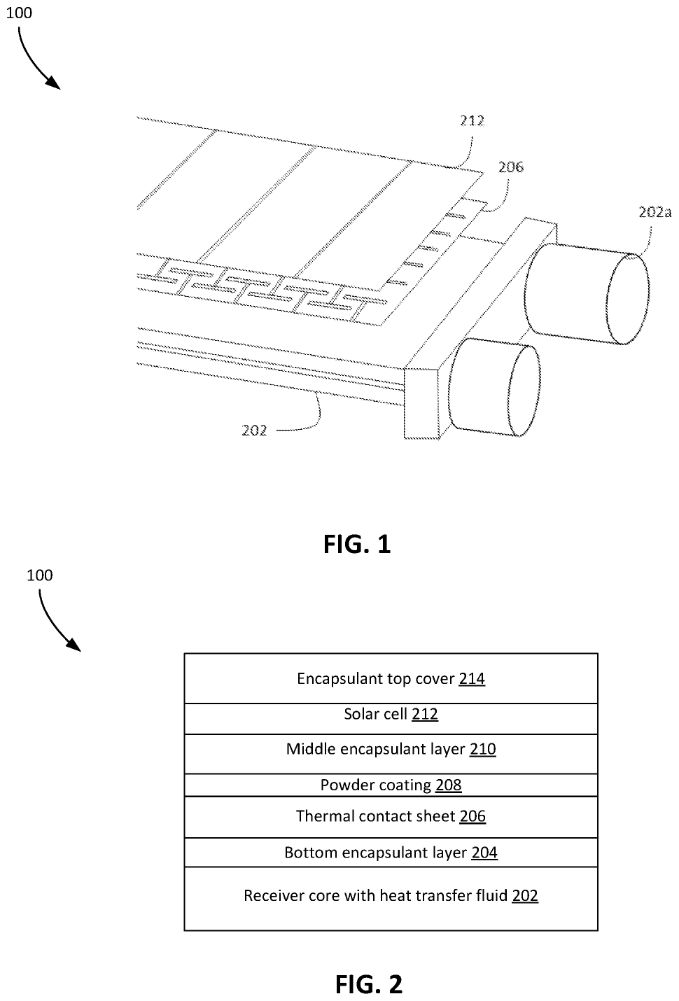

Various embodiments will now be described by way of example and with reference to FIG. 1-4. It should be noted that these embodiments are only non-limiting example embodiments and that the scope of the invention is defined by the claims. Further, it should be noted that the measurements used in the embodiments described below are merely exemplary, and that the thickness and dimensions, and materials of the various components may vary, based on the specific situation at hand. Any such variations are considered to be a matter of experimentation that lies well within the capabilities of a person having ordinary skill in the art.

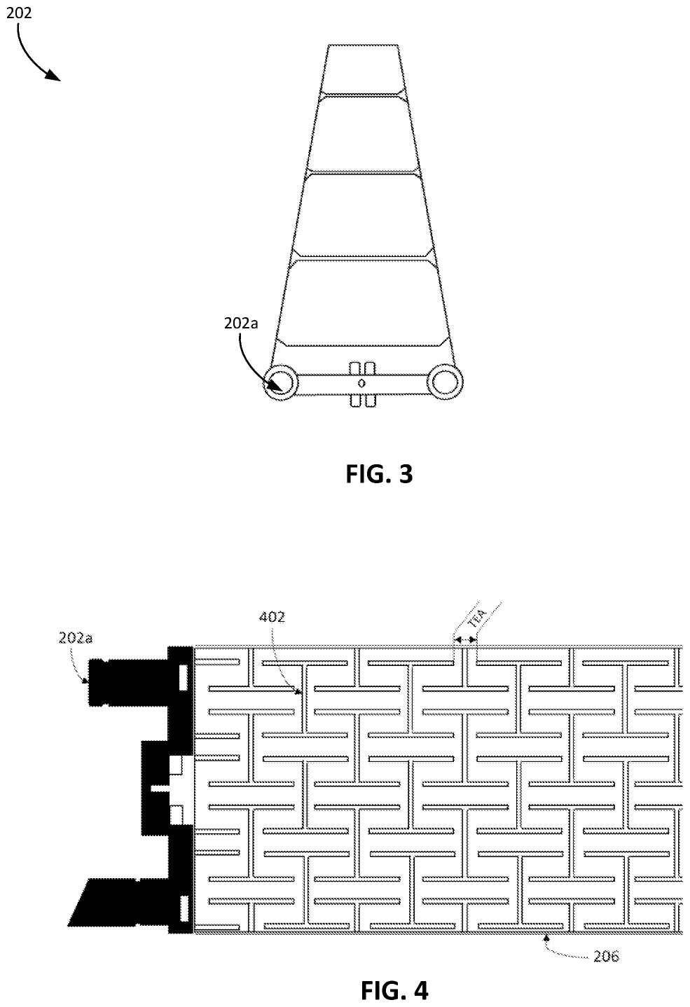

FIG. 1 shows a schematic exploded view of a PVT collector 100 in accordance with some embodiments, in which the different layers have been separated from one another. A corresponding schematic view of the PVT collector 100 is shown in FIG. 2. As can be seen in FIG. 2, the PVT collector 100 comprises a receiver core 202 which contains a heat transfer fluid, as described above. Typically, the heat transfer fluid is water, but other liquids, such as glycol or mineral oil, may also be used depending on the specific embodiment at hand. The heat transfer fluid enters the receiver core 202 through an inlet 202a, absorbs heat from the solar cells 212 and leaves the receiver core 202 through an outlet on the opposing side of the receiver. This system is then connected to an external system that uses the absorbed heat for some particular purpose as described above. A perspective view of the receiver core 202 is shown in FIG. 3 to provide a better understanding of what the receiver core 202 looks like as a whole.

On top of the receiver core 202, sits a thin encapsulant layer 204, whose main purpose is to attach a thermal contact sheet 206 to the receiver core 202. In the illustrated embodiment the thin encapsulant layer 204 is approximately 0.2 mm thick and made from silicone, such as Elastosil 2205. However, again, it should be noted that the materials and thickness of the thin encapsulant layer 204 may vary. In some embodiments, the thickness can be as small as 0.1 mm and in others, the thickness can be as large as 0.5 mm.

The thermal contact sheet 206 in the illustrated embodiment is an aluminum sheet having a thickness of 0.5 mm, and which contains a plurality of through holes arranged in a pattern, which allows thermal expansion and contraction of the thermal contact sheet 206 in various directions. In the illustrated embodiment, the thermal contact sheet 206 is covered with a powder coating 208, which further reduces the electrical conductance of the thermal contact sheet 206. In the illustrated embodiment the powder coating 208 is a black Resicoat powder and has a thickness of approximately 0.02 mm. However, other thicknesses and materials are also possible. The size of the thermal contact sheet 206 can vary greatly and can be anywhere in the range of approximately 10×10 mm through 2×2 m, depending on the size of the PVT collector 100. Further details of the thermal contact sheet 206 and powder coating 208 will be described below.

A thin encapsulant layer 210, again made of silicone, such as Elastosil 2205, and having a thickness of approximately 0.5 mm covers the thermal contact sheet 206 with the powder coating 208. Similar to the thin encapsulant layer 204, the purpose of the thin encapsulant layer 210 is to attach the thermal contact sheet 206 with the powder coating 208 to the next layer, which is the solar cells 212. And similar to the thin encapsulant layer 204, the thickness of the thin encapsulant layer 210 can vary, typically anywhere from about 0.1 mm to about 0.5 mm. In the illustrated embodiment of the PVT collector 100, the solar cells 212 has a thickness of approximately 0.4 mm. Finally, the topmost layer of the PVT collector 100 is another encapsulant top cover 214, having a thickness of approximately 1 mm, and whose purpose is to protect the solar cells 212. Again, in the preferred embodiment, the encapsulant top cover 214 is made of silicone, such as Elastosil 2205 but other materials can be utilized for the same purpose. Typically, the PVT collector 100 is also protected with a strong hail-proof solar glass on top and a support frame on the bottom, which can be mounted to a surface, such as the roof of a building, etc.

FIG. 4 shows a detailed top view of an embodiment of the thermal contact sheet 206. As was described above, the thermal contact sheet 206 is designed to allow for thermal expansion and contraction by using a number of through holes 402 (simply referred to herein as “holes”) arranged in a pattern across the thermal contact sheet 206, which enhances the longevity of the PVT collector 100 and reduces the risk of cracking of the solar cells 212. The holes 402 can all have the same shape, or have different shapes. The holes 402 can all have the same size, or have different sizes. The holes 402 can be uniformly distributed across the thermal contact sheet 206 or be concentrated to certain areas of the thermal contact sheet 206. Generally, the combined cross-sectional area of the holes 402 is somewhere in the range of 7-70% of the total surface area of the thermal contact sheet 206, but again, this percentage may vary widely depending on the particular situation at hand (e.g., material, temperature ranges, etc.). The relevant surface area for this calculation is the area under directly by the cell's strings. Thermal expansion simulations can provide information regarding the appropriate dimensions and configuration for the pattern of the holes and allow the skilled artisan to make the appropriate decisions with the goal of preventing cracking the individual solar cells 212 or a string of solar cells 212.

As can be seen in FIG. 4, the holes 402 are shaped similar to the letter H to accommodate for expansion and contraction in two perpendicular directions. However, it should be realized that many other shapes of holes 402 can achieve the same purpose of allowing expansion and contraction of the thermal contact sheet 206 in different directions, such as L-, M-, C-, Z- and W-shapes, just to mention a few alternatives. It should be noted that the shape of the through holes is not limited to letters of the alphabet, and that essentially any shape of through holes that allow for expansion and contraction in two perpendicular directions can be used. Either a single shape can be used throughout the thermal contact sheet 206, or a combination of two or more shapes can be used on the thermal contact sheet 206. In one embodiment, the spacing between the H-patterns is anywhere in the range from approximately 3 mm to approximately 30 mm.

The hole pattern illustrated in FIG. 4 is divided into two different areas: an Internal Expansion Area (IEA) and a Total Expansion Area (TEA). The IEA is the part of the hole pattern where the thermal expansion and contraction is mitigated by the design geometry.

That is, one “leg” of the H-shaped hole expands in one direction and while the other leg expands in the opposite direction. In this way, the total expansion is unaffected when expansion occurs in the IEA. The TEA is the part of the design pattern where the expansion affects the overall expansion of the thermal contact sheet 206. By controlling the size of the TEA with respect to the total area of the thermal contact sheet 206, the value of the total expansion of the thermal contact sheet 206 can be determined. As can be realized by those having ordinary skill in the art, the length of the “legs” in the H-shaped hole pattern affects the total expansion (e.g., longer legs will give less total expansion as the holes 402 can absorb a larger portion of the total expansion compared to holes having shorter legs).

It should be noted that any preparation of the thermal contact sheet 206, such as creating the holes 402, can be done outside of the assembly line for the PVT collector 100, and the extra time needed to place the thermal contact sheet 206 in the PVT collector 100 is significantly faster compared to the conventional alternative of arranging electrical insulators, such as Kapton tape, in the PVT collector 100. This reduces the overall assembly time on the receiver assembly line. It should further be noted that FIG. 4 only illustrates a portion of a thermal contact sheet 206, and that the thermal contact sheet 206 and hole pattern can be made in any sizes, such as the size of a solar cell 212, a string of solar cells 212, or even a full PVT receiver 100, depending on the particular situation at hand. As was mentioned above, the size of the thermal contact sheet 206 may be anywhere from 10×10 mm to 2×2 m. Such modifications lie well within the capabilities of those having ordinary skill in the art.

The thin encapsulant layers 204 and 210 on either side of the thermal contact sheet 206 allow the thermal contact sheet 206 to move relative to the receiver core 202 and solar cells 212. This configuration contributes to the longevity of the PVT collector 100 as the risk of cracking of the solar cells 212 due to differential thermal expansion between the receiver core 202 and solar cells 212 is significantly reduced. Furthermore, the combination of a highly electrically pre-insulated thermal contact sheet 206 and encapsulant layers 202 and 210 increase the electrical insulation compared to existing solutions that do not contain any thermal contact sheet 206. The thin encapsulant layer 204 and thermal contact sheet 206, respectively, allow the solar cells 212 to rest against the thermal contact sheet 206, thus maximizing the thermal conductivity of the thermal contact sheet 206, while at the same increasing the safety margin on the insulation side.

The thickness of the thermal contact sheet 206 should be as thin as possible, while providing satisfactory properties for production and being able to withstand the expansion of the thick receiver core 202. Typically, the thickness of the thermal contact sheet 206 is somewhere in the general range of 0.2-4.0 mm. Generally, a variation in the thickness of the aluminum presents a smaller difference in thermal conductivity values than what is seen when the thickness of the thin encapsulant layer 204 varies. This is due to the lower thermal conductivity of encapsulant by factor of approximately 1000 compared to that of aluminum (silicone has a thermal conductivity of approximately 0.2 [W/m·K], whereas aluminum has a thermal conductivity of approximately 200 [W/m·K]).

The various embodiments described herein result in a number of advantages compared to conventional PVT collector configurations, such as:
Improved Thermal Efficiency: As metal conducts heat better than an encapsulant, such as silicone, the thermal contact is improved compared to conventional PVT collector configurations. While the thermal conductivity is not improved by a factor 1000 in all embodiments (since there is still some encapsulant present, as described above), there is still a significant increase in the heat transfer to the working fluid, which translates into increased thermal performance for the PVT collector 100.
Production Process Reliability: The production process of the PVT collectors 100 in accordance with the various embodiments described above has increased reliability with respect to electrical insulation. Speed and complexity of the process are also improved
Improved Electrical Efficiency: When running at the same inlet temperature, two similar PVT collectors, one with the thermal contact sheet and one without the thermal contact sheet, the PVT collector with the thermal contact sheet has its solar cells operating at a lower temperature, which translates into a higher efficiency for the PVT collector.
Increased durability: As noted above, the encapsulant protects the cells from the thermal expansion of the thermal receiver. This is a vital function for the PVT collector to work. The embodiments of the PVT collectors described above provide increased thermal expansion and contraction resistance by allowing thermal expansion in all directions through holes of the thermal contact sheet. As a result, there will be less overall expansion of the thermal receiver in any single direction and thus a significantly diminished the risk of cell cracking, which extends the lifetime of the solar cells.
Cheaper PVT collectors: By significantly reducing the amount of transparent encapsulant (in some embodiments up to about 80%) used in the encapsulation of the solar cells, a significant overall cost reduction can be achieved for PVT collectors, as the receiver cost typically represents about 80% of the total PVT collector cost.

It will be apparent to those skilled in the art that various modifications and variations can be made in the disclosed structures and methods without departing from the scope or spirit of the invention. For example, while the above embodiments have referred to thermal contact sheet 206 made from aluminum, there may be other metals that have similar properties and performance, such as aluminum alloys, copper, ceramics, brass, fiber plastics, or other types of plastics and similar materials. In some embodiments, ceramics or even plastic can be used as an alternative material for the thermal contact sheet 206.

Further, while some of the embodiments described above use a powder coating 208, there may be other substances that have electrically insulating properties and that could advantageously be used instead of a powder coating, or in combination with a powder. For example, the electrical insulation could be achieved through a film cover or anodization or similar treatment. Also, while the encapsulant has been described by way of example as silicone, and in particular Elastosil, it should be noted that there are other encapsulants that can be used as well, which have similar properties to silicone. In some alternative embodiments, it may even be possible to forego the thin encapsulant layers 204 and 210 altogether, which decreases both the complexity and cost of the production process of the PVT collector 100. Thus, other embodiments of the invention will be apparent to those skilled in the art from consideration of the specification and practice of the invention disclosed herein. It is intended that the specification and examples be considered exemplary only, with a true scope and spirit of the invention being indicated by the following claims.

1. A photovoltaic thermal collector, comprising:
a plurality of photovoltaic cells;
a heat exchanger comprising a working fluid; and
a thermal contact sheet disposed entirely between the plurality of photovoltaic cells and the heat exchanger, the thermal contact sheet being configured to provide thermal contact between the plurality of photovoltaic cells and the heat exchanger, wherein the sheet comprises a plurality of H-shaped through holes arranged on the sheet so as to provide thermal expansion resistance of the sheet in a plurality of directions, by absorbing at least part of the thermal expansion of the sheet into the through holes.

2. The thermal contact sheet of claim 1, wherein the sheet is made from one of the following materials: aluminum, aluminum alloys, copper, ceramics, brass, fiber plastics, and plastics.

3. The thermal contact sheet of claim 1, wherein the sheet has a thickness in the range of approximately 0.2 mm to 4.0 mm.

4. (canceled)

5. The thermal sheet of claim 1, wherein at least some of the through holes are shaped as slits.

6. The thermal contact sheet of claim 5, further including through holes shaped similar to one or more of the letters L M, C, Z and W.

7. The thermal contact sheet of claim 1, wherein the through holes are evenly distributed across the sheet.

8. The thermal contact sheet of claim 1, wherein the distance between the holes is in the range of approximately 3-30 mm.

9. The thermal contact sheet of claim 1, wherein the combined cross-sectional area of the through holes is in the range of approximately 7-70 percent of the surface area of the portion of the sheet that is located directly below the photovoltaic cells.

10. The thermal contact sheet of claim 1, wherein the sheet further comprises an electrical insulation on one or both sides of the sheet.

11. The thermal contact sheet of claim 10, wherein the electrical insulation is achieved by one or more of: a powder coating, an insulating film, and anodization.

12. The thermal contact sheet of claim 1, wherein the through holes are filled with an encapsulant to increase the protection of the photovoltaic cells against thermal expansion and contraction of the thermal contact sheet.

13. The thermal contact sheet of claim 12, wherein the encapsulant is one of: silicone and Ethylene-vinyl acetate.

14. (canceled)
